(19) United States
(12) Patent Application Publication
(10) Pub. No.: US 2025/0328072 A1
(43) Pub. Date: Oct. 23, 2025

(54) METHOD OF CORRECTING AN ERROR OF A LAYOUT OF A PATTERN AND METHOD OF FORMING A PATTERN USING THE SAME

(71) Applicant: SAMSUNG ELECTRONICS CO., LTD, SUWON-SI (KR)

(72) Inventors: Hyeok LEE, Suwon-si (KR); Jaewon YANG, Suwon-si (KR); Mincheol KANG, Suwon-si (KR); Sangwook KIM, Suwon-si (KR)

(21) Appl. No.: 19/066,953

(22) Filed: Feb. 28, 2025

(30) Foreign Application Priority Data
Apr. 23, 2024 (KR) 10-2024-0053755

(51) Int. Cl. G03F 1/70; G03F 1/36; G03F 1/72; G03F 1/76; G03F 7/00; G06F 30/392; G06F 30/398

(52) U.S. Cl. CPC G03F 1/70; G03F 1/36; G03F 1/72; G03F 1/76; G03F 7/70441; G06F 30/392; G06F 30/398

(57) ABSTRACT

A method of correcting a layout of a pattern includes: designing a layout of an original ADI target including target patterns; applying a plurality of biases to the target patterns to design a random biased ADI target including biased patterns; manufacturing a first photomask and a second photomask corresponding to the original ADI target and the random biased ADI target, respectively; performing an exposure process and a developing process on a photoresist layer by using the first and second photomasks to form first and second photoresist patterns, respectively; performing an etching process on an etching object layer by using the first and second photoresist patterns to form first and second patterns, respectively; measuring CDs of the first and second patterns to calculate a REEF; generating a PPC model by using the REEF; and performing a PPC by using the PPC model to correct the layout of the original ADI target.

### CROSS-REFERENCE TO RELATED APPLICATION

This application claims priority under 35 U.S.C. § 119 to Korean Patent Application No. 10-2024-0053755, filed on Apr. 23, 2024 in the Korean Intellectual Property Office (KIPO), the disclosure of which is incorporated by reference herein in its entirety.

### TECHNICAL FIELD

Example embodiments of the present inventive concept relate to a method of correcting an error of a layout of a pattern and a method of forming a pattern using the same.

### DISCUSSION OF RELATED ART

Generally, a layout of a target pattern having a desired shape is first designed, followed by applying optical proximity correction (OPC) to correct the layout of the target pattern. Based on the corrected layout, a photomask is manufactured. Using this photomask, a photoresist pattern is formed, which is then used to etch an object layer on a wafer to form a real pattern. However, there may be an error of a critical dimension (CD) or an overlay mismatch between a layout of the real pattern and the designed layout of the target pattern, so that a correction is needed.

### SUMMARY

According to example embodiments of the present inventive concept, a method of correcting a layout of a pattern includes: designing a layout of an original after development inspection (ADI) target, wherein the original ADI target includes target patterns; applying a plurality of biases to the target patterns to design a random biased ADI target, wherein the random biased ADI target includes biased patterns; manufacturing a single first photomask and a single second photomask corresponding to the original ADI target and the random biased ADI target, respectively; performing an exposure process and a developing process on a photoresist layer by using the first and second photomasks to form first and second photoresist patterns, respectively, in the photoresist layer; performing an etching process on an etching object layer by using the first and second photoresist patterns to form first and second patterns, respectively, in the etching object layer; measuring critical dimensions (CDs) of the first and second patterns to calculate a retarget error enhancement factor (REEF); generating a process proximity correction (PPC) model by using the REEF; and performing a PPC by using the PPC model to correct the layout of the original ADI target.

According to example embodiments of the present inventive concept, a method of correcting a layout of a pattern includes: designing a layout of an original mask target, wherein the original mask target includes target patterns; applying a plurality of biases to the target patterns to design a random biased mask target, wherein the random biased mask target includes biased patterns; manufacturing a single first photomask and a single second photomask corresponding to the original mask target and the random biased mask target, respectively; performing an exposure process and a developing process on a photoresist layer by using the first and second photomasks to form first and second photoresist patterns, respectively; measuring critical dimensions (CDs) of the first and second photoresist patterns to calculate a mask error enhancement factor (MEEF); generating an optical proximity correction (OPC) model by using the MEEF; and performing an OPC by using the OPC model to correct the layout of the original mask target.

According to example embodiments of the present inventive concept, a method of forming a pattern includes: designing a layout of an original after development inspection (ADI) target, wherein the original ADI target includes target patterns; applying a plurality of biases to the target patterns to design a random biased ADI target, wherein the random biased ADI target includes biased patterns; manufacturing a single first photomask and a single second photomask corresponding to the original ADI target and the random biased ADI target, respectively; performing an exposure process and a developing process on a photoresist layer by using the first and second photomasks to form first and second photoresist patterns, respectively, in the photoresist layer; performing an etching process on a first etching object layer by using the first and second photoresist patterns to form first and second patterns, respectively, in the etching object layer; measuring critical dimensions (CDs) of the first and second patterns to calculate a retarget error enhancement factor (REEF); generating a process proximity correction (PPC) model by using the REEF; performing a PPC by using the PPC model to firstly correct the layout of the original ADI target; manufacturing a third photomask based on the firstly corrected layout of the original ADI target; sequentially forming a second etching object layer and a second photoresist layer on a first substrate; performing an exposure process and a developing process on the second photoresist layer by using the third photomask to form a third photoresist pattern in the second photoresist; and performing an etching process on the second etching object layer by using the third photoresist pattern as an etching mask to form a third pattern in the second etching object layer.

### BRIEF DESCRIPTION OF THE DRAWINGS

FIG. 1 is a flowchart illustrating a method of calculating a REEF in accordance with example embodiments of the present inventive concept.

FIGS. 2 and 3 are plan views illustrating an original ADI target and a biased ADI target generated from the original ADI target in accordance with example embodiments of the present inventive concept.

FIGS. 4A, 4B, and 4C are bar graphs illustrating a distribution of the biased ADI target.

FIG. 5 is a flowchart illustrating a method of correcting a layout of a pattern, a method of manufacturing a photomask using the same, and a method of forming a pattern using the same in accordance with example embodiments of the present inventive concept.

FIGS. 6 and 7 are cross-sectional views illustrating the method of forming the pattern.

### DETAILED DESCRIPTION OF THE EMBODIMENTS

The above and other features of the present inventive concept will be more clearly understood by describing in detail exemplary embodiments thereof with reference to the accompanying drawings.

Patterns on a wafer may be formed by forming an etching object layer on the wafer, forming a photoresist layer on the etching object layer, patterning the photoresist layer to form a photoresist pattern, and etching the etching object layer by using the photoresist pattern as an etching mask. An additional etching mask layer may be formed between the etching object layer and the photoresist layer, and in this case, the etching mask layer may be etched by using the photoresist pattern to form an etching mask, and the etching object layer may be etched using the etching mask.

The formation of the photoresist pattern by patterning the photoresist layer may be performed by placing a photomask, e.g., a reticle including a given pattern over the photoresist layer, performing an exposure process in which a light is emitted from a light source to penetrate through the photomask to the photoresist layer, and performing a developing process in which, based on the type of photoresist layer, a portion of the photoresist layer, either exposed or unexposed to the light, is removed, so that a layout of the given pattern may be transferred to the photoresist layer.

For example, a deep ultraviolet (DUV) equipment using KrF or ArF as a light source has been used, and recently, an extreme ultraviolet (EUV) equipment has also been used. However, the DUV equipment is mainly used due to the high cost of the EUV equipment.

As a pattern on a wafer is miniaturized, optical proximity effect (OPE) may arise due to the close proximity of neighboring patterns during an exposure process, and optical proximity correction (OPC) may be performed to correct a layout of a pattern on a photomask.

Additionally, a layout of a pattern that is formed by etching an etching object layer by using a photoresist pattern as an etching mask might not be exactly the same as a layout of the photoresist pattern due to loading effect or misalignment in the etching process or unique characteristics of the etching process, and thus, process proximity correction (PPC) for correcting the layout of the photoresist pattern so that a real pattern on a wafer may have a desired layout may be performed.

It is desirable to generate a model having a high accuracy to perform the OPC or the PPC, which may be enhanced by securing a tool which may predict a change of a critical dimension (CD) of a photoresist pattern according to a change of a CD of a photomask, or predict a change of a CD of a pattern, for an etching object layer, according to the change of the CD of the photoresist pattern.

A real pattern on a wafer may be formed according to a design of an after cleaning inspection (ACI) target. A photoresist pattern serving as an etching mask in an etching process for forming the real pattern may be formed according to a design of an after development inspection (ADI) target, and a photomask used in an exposure process and a development process for forming the photoresist pattern may be formed according to a design of a mask target.

A ratio of the change of the CD of the photoresist pattern with respect to the change of the CD of the mask target may be defined as a mask enhancement error factor (MEEF), and a ratio of the change of the CD of the real pattern with respect to the change of the CD of the ADI target may be defined as a retarget enhancement error factor (REEF).

That is, if the photoresist pattern does not have a desired CD, the CD of the mask target may be correct; however, the relationship between the change of the CD of the mask target and the change of the CD of the photoresist pattern is not one-to-one correspondence, and thus, the ratio of the CD of the change of the photoresist pattern with respect to the change of the CD of the mask target, which is the MEEF, may be acquired to be reflected in changing the CD of the mask target so that the CD of the photoresist pattern may be more exactly corrected to have a desired CD.

Likewise, if the real pattern does not have a desired CD, the CD of the ADI target may be correct; however, the relationship between the change of the CD of the ADI target and the change of the CD of the real pattern is not one-to-one correspondence, and thus, the ratio of the CD of the change of the real pattern with respect to the change of the CD of the ADI target, which is the REEF, may be acquired to be reflected in changing the CD of the ADI target so that the CD of the real pattern may be more exactly corrected to have a desired CD.

To acquire the MEEF, for example, a bias may be applied to an original mask target to vary a CD of the original mask target so that biased mask targets may be formed. In addition, photomasks corresponding to the original mask target and the biased mask targets may be manufactured, and an etching object layer and a photoresist layer may be formed on a wafer.

Further, an exposure process and a development process may be performed on the photoresist layer by using each of the manufactured photomasks to form a photoresist pattern. In addition, a CD of the photoresist pattern, which is a CD of a first photoresist pattern formed by a first photomask that is manufactured according to the original mask target, and a CD of the photoresist pattern, which is a CD of a second photoresist pattern formed by a second photomask that is manufactured according to the biased mask target, may be measured.

The MEEF is a ratio of a difference between the CD of the second photoresist pattern and the CD of the first photoresist pattern, that is, a change of the CD of the photoresist pattern with respect to a difference between the CD of the biased mask target and the CD of the original mask target, that is, a change of the CD of the mask target, and thus the MEEF may be calculated from the measurements of the CDs of the first and second photoresist patterns, the original mask target and the biased mask target.

The biased mask targets may be generated by applying, for example, a global bias, a horizontal bias and a vertical bias to the original mask target, and each of the biased mask targets may include a plus bias or a minus bias that may increase or decrease, respectively, the CD of the original mask target. Thus, for example, six biased targets may be generated from a single original mask target.

In this case, to acquire the MEEF, seven photomasks including one photomask according to the original mask target and six photomasks according to the biased mask targets may be manufactured, and CDs of photoresist patterns formed by exposure processes and development processes using the seven photomasks may be measured, which may require a large amount of time.

Likewise, to acquire the REEF, for example, a bias may be applied to an original ADI target to vary a CD of the original ADI target so that biased ADI targets may be formed. In addition, photomasks corresponding to the original ADI target and the biased ADI targets may be manufactured, and an etching object layer and a photoresist layer may be formed on a wafer.

Further, an exposure process and a development process may be performed on the photoresist layer by using each of the manufactured photomasks to form a photoresist pattern, and an etching process may be performed on the etching object layer to form a real pattern on the wafer. In addition, a CD of the real pattern, which is a CD of a first real pattern that is formed by a third photomask manufactured according to the original ADI target, and a CD of the real pattern, which is a CD of a second real pattern that is formed by a fourth photomask manufactured according to the biased ADI target, may be measured.

The REEF is a ratio of a difference between the CD of the second real pattern and the CD of the first real pattern, that is, a change of the CD of the real pattern with respect to a difference between the CD of the biased ADI target and the CD of the original ADI target, that is, a change of the CD of the ADI target, and thus the REEF may be calculated from the measurements of the CDs of the first and second real patterns, the original ADI target and the biased ADI target.

The biased ADI targets may be generated by applying, for example, a global bias, a horizontal bias and a vertical bias to the original ADI target, and each of the biased AID targets may include a plus bias or a minus bias that may increase or decrease, respectively, the CD of the original ADI target. Thus, for example, six biased ADI targets may be generated from a single original ADI target.

In this case, to acquire the REEF, seven photomasks including one photomask according to the original ADI target and six photomasks according to the biased ADI targets may be manufactured, and CDs of real patterns formed by exposure processes, development processes and etching processes using the seven photomasks may be measured, which may require a large amount of time.

Hereinafter, a method of acquiring the MEEF and the REEF more efficiently and a method of correcting a layout of a pattern are illustrated.

Example embodiments of the present inventive concept provide methods to correct layout errors in semiconductor manufacturing patterns. The method may reduce distortions caused by proximity effects during photolithography, such as critical dimension (CD) variations and overlay mismatches. These errors may be addressed by using techniques like Optical Proximity Correction (OPC) and Process Proximity Correction (PPC). By using biases—controlled adjustments to pattern dimensions—the method may increase accuracy and efficiency in semiconductor manufacturing.

According to example embodiments of the present inventive concept, random biases (e.g., horizontal, vertical, and global) may be applied to target patterns in the design stage. These biases help simulate manufacturing distortions, enabling the calculation of enhancement factors such as the Mask Error Enhancement Factor (MEEF) and the Retarget Error Enhancement Factor (REEF). These factors are integrated into machine learning models to predict and mitigate errors. This may eliminate the need for multiple photomasks and extensive data collection, saving significant cost and time.

According to example embodiments of the present inventive concept, the method may include designing two photomasks—one for the original pattern and another for the biased pattern. The patterns formed on a wafer by using these photomasks are analyzed to measure CD variations and calculate enhancement factors. These measurements refine the PPC and OPC models, enabling precise correction of the original layout.

The method, according to example embodiments of the present inventive concept, may reduce the time, cost, and complexity associated with traditional correction methods while achieving higher fidelity in pattern formation. The approach may ensure that the final patterns closely match the intended design, even as feature sizes shrink to nanometer scales.

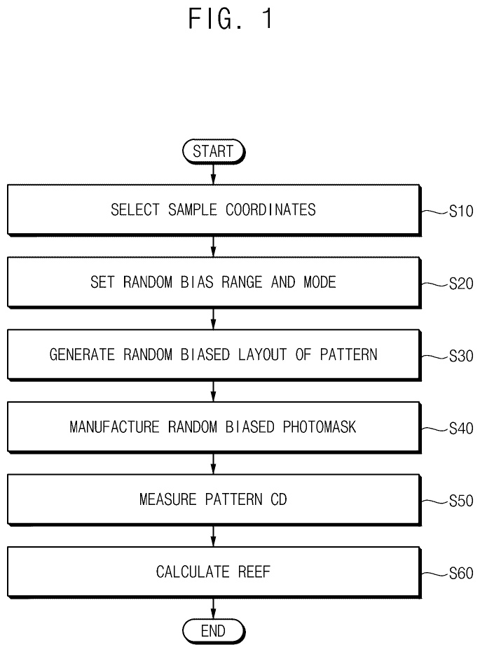

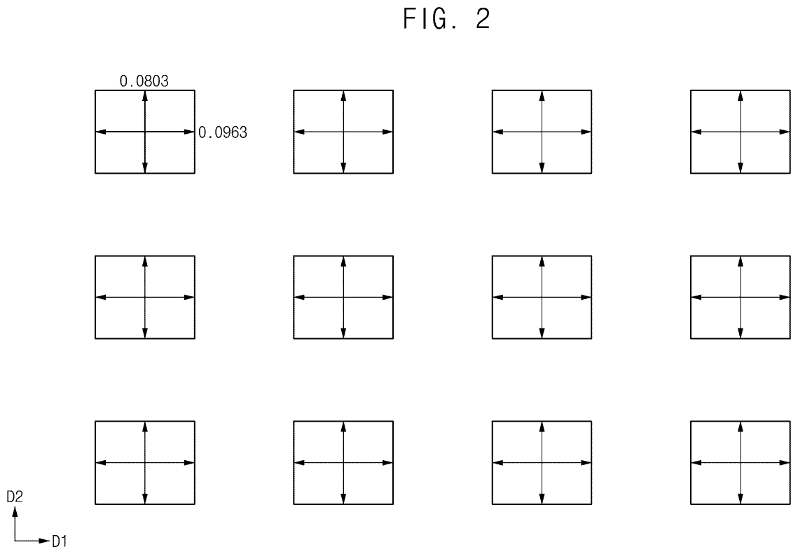

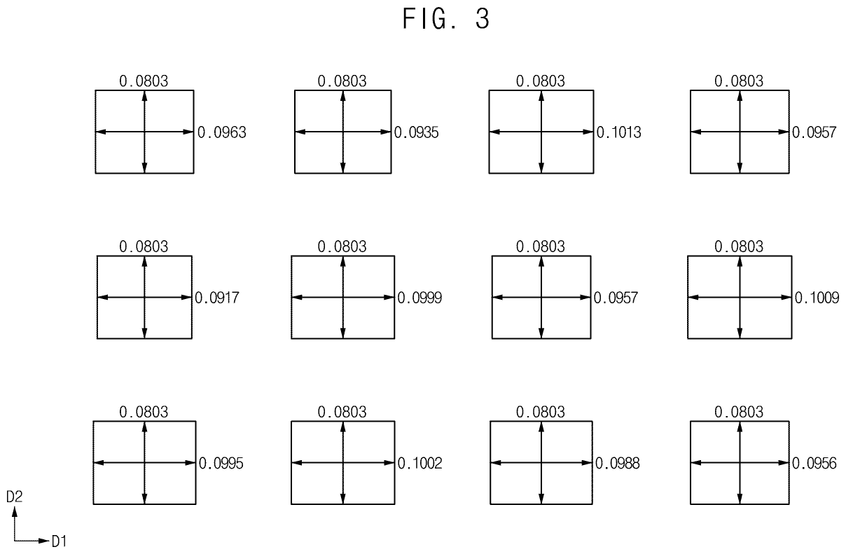

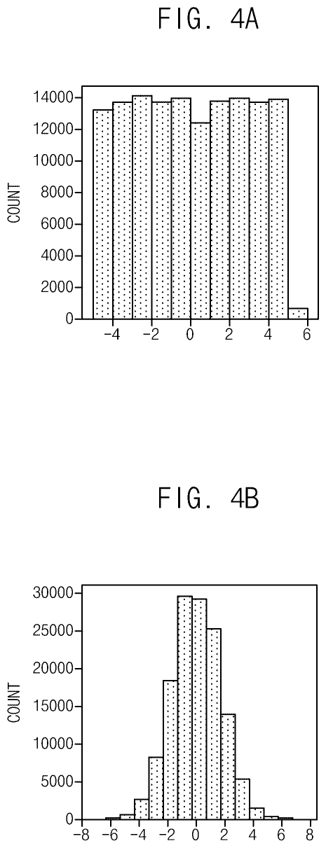

FIG. 1 is a flowchart illustrating a method of calculating a REEF in accordance with example embodiments of the present inventive concept. FIGS. 2 and 3 are plan views illustrating an original ADI target and a biased ADI target that is generated from the original ADI target in accordance with example embodiments of the present inventive concept, and FIGS. 4A, 4B, and 4C are bar graphs illustrating a distribution of the biased ADI target.

Referring to FIGS. 1 to 4C, in step S10, coordinates of a sample pattern to which a bias is applied may be selected in an original ADI target.

In example embodiments of the present inventive concept, the original ADI target may include a plurality of target patterns, which may have a shape of a rectangle, spaced apart from each other in each of first and second directions D1 and D2, and the coordinates of a sample pattern selected from the plurality of target patterns may include, e.g., coordinates of edges of the rectangle of the sample pattern.

Each of the target patterns may include a long axis extending in the first direction D1 and a short axis extending in the second direction D2 that is substantially perpendicular to the first direction D1, and FIG. 2 shows that the long axis has a length of about 0.0963 and that the short axis has a length of about 0.0803. However, the present inventive concept is not limited thereto, and each of the target patterns may include a long axis extending in the second direction D2 and a short axis extending in the first direction D1.

In example embodiments of the present inventive concept, the sample pattern may be one, some, or all of the plurality of target patterns that are included in the original ADI target, and FIG. 2 shows some of the sample patterns.

In step S20, a range of a bias to be applied to the selected sample patterns may be set.

In example embodiments of the present inventive concept, the bias may be applied to the long axis and the short axis of each of the sample patterns, and the bias applied to each of the long axis and the short axis might not have a specific value but may have various random values in a predetermined range. For example, the bias applied to each of the long axis and the short axis may be set to have a range of about −5 nm to about +5 m. In addition, the bias applied to each of the long axis and the short axis may be set to have a range of about −5% to about +5%.

As the bias may have the various random values in the predetermined range, the bias may also be referred to as a random bias.

A distribution of the values of the random bias in the predetermined range, which may be referred to as a mode, may be set.

The mode of the random bias may have a uniform distribution as shown in FIG. 4A, a Gaussian distribution as shown in FIG. 4B, or a shifted Gaussian distribution as shown in FIG. 4C.

For example, if the random bias of the length of the long axis has a range of about −5 nm to about +5 nm, the number of sample patterns included in respective sections in the range may be the same as each other, the number of sample patterns included in respective sections gradually decrease as the sections get farther from zero, or the number of sample patterns included in respective sections gradually increase as the sections get farther from zero.

In step S30, the random bias set in step S20 may be applied to the original ADI target so as to generate a random biased ADI target.

As the random bias is applied to the original ADI target, the length of the long axis and/or the length of the short axis of each of the sample patterns may be changed to generate the random biased ADI target, and FIG. 3 shows sample patterns that are generated by changing the lengths of the long axes of the sample patterns included in the ADI target.

In example embodiments of the present inventive concept, the random biased ADI target may include first biased patterns, which may be generated by changing the lengths of the long axes of some of the sample patterns, second biased patterns, which may be generated by changing the lengths of the short axes of other ones of the sample patterns, and third biased patterns, which may be generated by changing both the lengths of the long axes and the lengths of the short axes of other ones of the sample patterns. That is, all of the horizontal bias, the vertical bias and the global bias may be applied to the original ADI target; however, the sample patterns included in the original ADI target may be classified into a plurality of groups, and the horizontal bias, the vertical bias and the global bias may be applied to ones of the sample patterns included in the groups, respectively.

In example embodiments of the present inventive concept, a length of a long axis of each of the first biased patterns, a length of a short axis of each of the second biased patterns, and a length of a long axis and a length of a short axis of each of the third biased patterns may be greater or smaller than the length of the long axis and the length of the short axis of each of the sample patterns.

Each of the horizontal bias, the vertical bias and the global bias that are applied to the original ADI target may include a plus bias and a minus bias. If the plus bias is applied, the length of the long axis of each of the first biased patterns, the length of the short axis of each of the second biased patterns, and the length of the long axis and the length of the short axis of each of the third biased patterns may be greater than the length of the long axis and the length of the short axis of each of the sample patterns. For example, the length of the long axis of each of the first biased patterns may be greater than the length of the long axis of each of the sample patterns, and the length of the short axis of each of the second biased patterns may be greater than the length of the short axis of each of the sample patterns. In addition, the length of the long axis and the length of the short axis of each of the third biased patterns may be greater than the length of the long axis and the length of the short axis of each of the sample patterns. If the minus bias is applied, the length of the long axis of each of the first biased patterns, the length of the short axis of each of the second biased patterns, and the length of the long axis and the length of the short axis of each of the third biased patterns may be smaller than the length of the long axis and the length of the short axis of each of the sample patterns. For example, the length of the long axis of each of the first biased patterns may be smaller than the length of the long axis of each of the sample patterns, and the length of the short axis of each of the second biased patterns may be smaller than the length of the short axis of each of the sample patterns. In addition, the length of the long axis and the length of the short axis of each of the third biased patterns may be smaller than the length of the long axis and the length of the short axis of each of the sample patterns.

In example embodiments of the present inventive concept, when the random bias is applied to each of the sample patterns, a bias having the same size may be applied to edges opposite to each other. For example, if a bias of about −2.1 is applied to a left edge, a bias of about −2.1 may also be applied to a right edge. Likewise, if a bias of about +3.2 is applied to an upper edge, a bias of about +3.2 may also be applied to a lower edge. Thus, coordinates of a center of each of the sample patterns and coordinates of a center of the biased pattern, which may be generated by applying a bias to each of the sample pattern, may be the same as each other.

In example embodiments of the present inventive concept, differences between lengths of the long axes of the first biased patterns and lengths of the long axes of corresponding ones of the sample patterns may be the same as or different from each other, differences between lengths of the short axes of the second biased patterns and lengths of the short axes of corresponding ones of the sample patterns may be the same as or different from each other, and differences between lengths of the long axes and the short axes of the third biased patterns and lengths of the long axes and the short axes, respectively, of corresponding ones of the sample patterns may be the same as or different from each other.

That is, the biases applied to the sample patterns of the original ADI target might not have the same value, but may have various random values in a predetermined range.

In step S40, a photomask may be manufactured according to the random biased ADI target.

That is, an original mask target corresponding to the original ADI target may be designed, and a first photomask may be manufactured according to the designed original mask target. Additionally, a random biased mask target corresponding to the random biased ADI target may be designed, and a second photomask may be manufactured according to the designed random biased mask target.

In example embodiments of the present inventive concept, a single second photomask may be manufactured per each first photomask. For example, the random biased ADI target may include the first to third biased patterns, which may be generated by applying all of the horizontal bias, the vertical bias and the global bias, respectively, to the sample patterns. Thus, a plurality of second photomasks including respective biased patterns, each of which is generated by applying only one of the horizontal bias, the vertical bias and the global bias to each of the sample patterns, might not be manufactured, and only one second photomask may be manufactured.

In step S50, an exposure process, a development process and an etching process may be performed by using each of the first and second photomasks to form a real pattern on a wafer, and a CD of the real pattern may be measured.

Table 1 shows CDs of the sample patterns included in the original ADI target and the biased patterns included in the random biased ADI target, CDs of the real patterns (real original patterns) on a wafer formed by using the first photomask manufactured according to the original ADI target, and CDs of the real patterns (real biased patterns) on a wafer formed by using the second photomask manufactured according to the random biased ADI target.

The CDs of the sample patterns that are included in the original ADI target and the biased patterns included in the random biased ADI target may include lengths of the long axes and lengths of the short axes, and the CDs of the real original patterns and the real biased patterns may include lengths of the long axes.

That is, a horizontal bias may be applied to the sample patterns included in the original ADI target to change the lengths of the long axes of the sample patterns so that the random biased ADI target may be generated, however, the change of the lengths of the long axes may affect the lengths of the short axes, and thus the lengths of the short axes are also written.

If a vertical bias is applied to the sample patterns included in the original ADI target to change the lengths of the short axes of the sample patterns so that the random biased ADI target is generated, the change of the lengths of the short axes may affect the lengths of the long axes, and thus the lengths of the long axes together with the lengths of the short axes may be needed.

The coordinates may include horizontal and vertical coordinates of edges of each of the sample patterns, amounting to four coordinates per pattern; however, for simplicity, these coordinates are represented by letters A to N in Table 1.

TABLE 1

| | | | length | length | length | length | |
|---|---|---|---|---|---|---|---|
| | | length | of long | of short | of long | of short | length |
| | | of long | axis of | axis of | axis of | axis of | of long |
| | | axis of | sample | sample | biased | biased | axis of |
| | | real | pattern of | pattern of | pattern of | pattern of | real |
| | coor- | original | original | original | biased | biased | biased |
| gauge | dinates | pattern | ADI target | ADI target | ADI target | ADI target | pattern |
| gauge 0 | A | 97.8 | 92.0 | 69.0 | 88.9 | 68.8 | 95.4 |
| gauge 1 | B | 95.5 | 92.0 | 69.0 | 94.3 | 71.8 | 99.9 |
| gauge 2 | C | 95.1 | 92.0 | 69.0 | 89.0 | 67.0 | 88.5 |
| gauge 3 | D | 97.5 | 92.0 | 69.0 | 89.8 | 69.2 | 96.3 |
| gauge 4 | E | 95.4 | 92.0 | 69.0 | 87.7 | 71.7 | 91.7 |
| gauge 5 | F | 97.3 | 92.0 | 69.0 | 91.1 | 69.0 | 91.7 |
| gauge 6 | G | 95.9 | 92.0 | 69.0 | 90.5 | 65.1 | 92.7 |
| gauge 7 | H | 96.3 | 92.0 | 69.0 | 94.6 | 71.0 | 97.6 |
| gauge 8 | I | 97.4 | 92.0 | 69.0 | 90.5 | 69.5 | 95.7 |
| gauge 9 | J | 96.1 | 92.0 | 69.0 | 87.9 | 67.4 | 93.4 |
| gauge 10 | K | 95.7 | 92.0 | 69.0 | 89.3 | 67.6 | 94.3 |
| gauge 11 | L | 95.4 | 92.0 | 69.0 | 88.5 | 71.9 | 92.4 |
| gauge 12 | M | 95.3 | 92.0 | 69.0 | 87.6 | 71.2 | 94.6 |
| gauge 13 | N | 99.3 | 92.0 | 69.0 | 90.9 | 69.6 | 96.3 |

In step S60, a REEF may be calculated based on the measured CDs of the real patterns.

The REEF may be a ratio of a change of a CD of a real pattern with respect to a change of a CD of a target pattern included in the ADI target. Thus, the REEF may be extracted by calculating a difference between the CD of the biased pattern included in the random biased ADI target and the CD of the target pattern included in the original ADI target, and a difference between the CD of the real biased pattern and the CD of the real original pattern. The CDs of the biased pattern included in the random biased ADI target and the target pattern included in the original ADI target may include, e.g., both lengths of a long axis and a short axis.

For example, a difference (Δtarget) between a length (cd2) of the long axis of the biased pattern included in the random biased ADI target and a length (cd1) of the long axis of the target pattern included in the original ADI target, a difference (Δref) between a length of the short axis of the biased pattern included in the random biased ADI target and a length of the short axis of the target pattern included in the original ADI target, and a difference (Δcd) between a length of the long axis of the real biased pattern and a length of the long axis of the real original pattern may be calculated.

In example embodiments of the present inventive concept, cd2 may be represented by a formula 1, which is a Taylor series including a constant term, a linear term and a quadratic term, as follows.

$$cd 2 = cd 1 + {a}_{0} Δ target + {a}_{1} Δ ref + {a}_{2} Δ target Δ ref + {a}_{3} Δ {target}^{2} + {a}_{4} Δ {ref}^{2} \qquad < Formula 1 >$$

Formula 1 may be transformed into Formula 2, and thus Δcd may be represented by a function of Δtarget and Δref, as follows.

$$Δ cd = {a}_{0} Δ target + {a}_{1} Δ ref + {a}_{2} Δ target Δ ref + {a}_{3} Δ {target}^{2} + {a}_{4} Δ {ref}^{2} \qquad < Formula 2 >$$

Values measured at gauge 0 of Table 1 may be input into Formula 2 so that a system of five linear equations with five unknowns is produced.

$$( 95.4 - 97. 8 ) = {a}_{0} ( 88.9 - 92. ) + {a}_{1} ( 6 8.8 - 69. 0 ) + {a}_{2} ( 8 8.9 - 92. 0 ) ( 6 8.8 - 69. 0 ) + {{a}_{3} ( 8 8.9 - 92. 0 )}^{2} + {{a}_{4} ( 6 8.8 - 69. 0 )}^{2}$$

Likewise, values measured at all gauges of Table 1 may be input into Formula 2 so that systems of five linear equations with five unknowns may be generated, and a₀, a₁, a₂, a₃ and a₄ may be calculated by regression analysis. The calculated a₀, a₁, a₂, a₃ and a₄ may be input into Formula 2 so that Δcd, which may be a function represented by Δtarget and Δref, may be acquired.

The REEF regarding the change of the long axis of the biased pattern that is included in the ADI target may be calculated with values in Table 1, however, the present inventive concept is not limited thereto, and for example, a REEF regarding the change of the short axis of the biased pattern that is included in the ADI target may also be calculated.

A left-hand side (Δcd) in Formula 2 is the change of the CD (the length of the long axis or the length of the short axis) of the real pattern, and a right-hand side (a₀Δtarget+a₁Δref+a₂ΔtargetΔref+a₃Δtarget²+a₄Δref²) in Formula 2 is a value corresponding to the change of the CD (the length of the long axis and the length of the short axis) of the ADI target pattern, and the REEF may correspond to a value that is obtained by dividing the left-hand side by the right-hand side.

Thus, the REEF might not have a single value with respect to the change of the lengths of all long axes of the ADI target pattern or a single value with respect to the change of the lengths of all short axes of the ADI target pattern, but may be obtained as a function of the changes of the lengths of each of the long axes of the ADI target pattern and a function of the changes of the lengths of each of the short axes of the ADI target pattern, so as to be more exactly calculated.

The REEF may be calculated by the above steps, and a MEEF may also be calculated by a similar method.

Particularly, the MEEF may be a ratio of a change of a CD of a photoresist pattern with respect to a change of a CD of a target pattern included in the mask target. Thus, the MEEF may be extracted by calculating a difference between the CD of the biased pattern that is included in the random biased mask target and the CD of the target pattern that is included in the original mask target, and a difference between the CD of the photoresist biased pattern and the CD of the photoresist original pattern. The CDs of the biased pattern that is included in the random biased mask target and the target pattern that is included in the original mask target may include, e.g., both lengths of a long axis and a short axis.

For example, a difference (Δtarget) between a length (cd4) of the long axis of the biased pattern that is included in the random biased mask target and a length (cd3) of the long axis of the target pattern that is included in the original mask target, a difference (Δref) between a length of the short axis of the biased pattern that is included in the random biased mask target and a length of the short axis of the target pattern included in the original mask target, and a difference (Δcd) between a length of the long axis of the photoresist biased pattern and a length of the long axis of the photoresist original pattern may be calculated.

In example embodiments of the present inventive concept, cd4 may be represented by a formula 3, which is a Taylor series including a constant term, a linear term and a quadratic term, as follows.

$$cd 4 = cd 2 + {b}_{0} Δ target + {b}_{1} Δ ref + {b}_{2} Δ target Δ ref + {b}_{3} Δ {target}^{2} + {b}_{4} Δ {ref}^{2} \qquad < Formula 3 >$$

Formula 3 may be transformed into Formula 4, and thus Δcd may be represented by a function of Δtarget and Δref, as follows.

$$Δ cd = {b}_{0} Δ target + {b}_{1} Δ ref + {b}_{2} Δ target Δ ref + {b}_{3} Δ {target}^{2} + {b}_{4} Δ {ref}^{2} \qquad < Formula 4 >$$

Values measured at all gauges may be input into Formula 4 so that systems of five linear equations with five unknowns may be generated, and b₀, b₁, b₂, b₃ and b₄ may be calculated by regression analysis. The calculated b₀, b₁, b₂, b₃ and b₄ may be input into Formula 4 so that Δcd, which may be a function represented by Δtarget and Δref, may be acquired.

Like the REEF, a MEEF regarding the change of the short axis of the biased pattern included in the mask target may also be calculated.

A left-hand side in Formula 4 is the change of the CD (the length of the long axis or the length of the short axis) of the photoresist pattern, and a right-hand side in Formula 4 is a value corresponding to the change of the CD (the length of the long axis and the length of the short axis) of the mask target pattern, and the MEEF may correspond to a value that is obtained by dividing the left-hand side by the right-hand side.

Thus, the MEEF might not have a single value with respect to the change of the lengths of all long axes of the mask target pattern or a single value with respect to the change of the lengths of all short axes of the mask target pattern, but may be obtained as a function of the changes of the lengths of each of the long axes of the mask target pattern and a function of the changes of the lengths of each of the short axes of the mask target pattern, so as to be more exactly calculated.

As illustrated above, to calculate the MEEF or REEF, instead of manufacturing six photomasks by applying, for example, plus and minus horizontal biases, plus and minus vertical biases, and plus and minus global biases to the original mask target or the original ADI target, only one photomask may be manufactured by randomly applying the biases to the original mask target or the original ADI target.

Thus, cost and time for manufacturing a plurality of photomasks, performing an exposure process, a developing process and an etching process using the plurality of photomasks to form photoresist patterns and real patterns on a wafer, and measuring CDs of the photoresist patterns and the real patterns may be reduced.

Particularly, when a modeling to estimate a MEEF or a REEF by using machine learning (ML), if a plurality of photomasks is used in addition to a photomask that corresponds to the original mask target or the original ADI target, a large amount of data has to be learned. However, in example embodiments of the present inventive concept, only one photomask may be added, so that the amount of data to be learned may be reduced, and the generation of the modeling may be efficiently performed.

Additionally, the bias applied to the original mask target or the original ADI target may have various values within a given range with respect to each direction, instead of having only one value. Thus, the MEEF and the REEF may be more exactly calculated based on the various measured values.

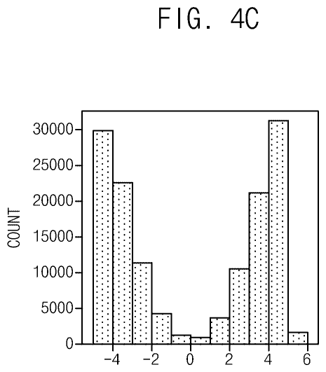

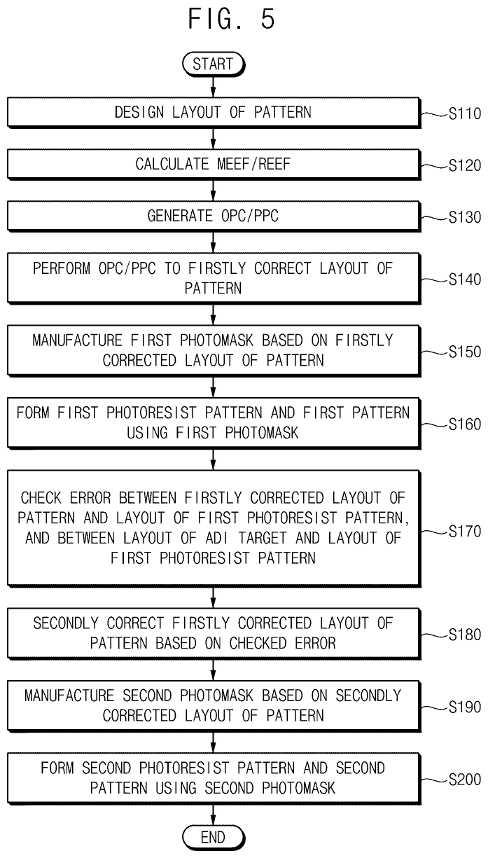

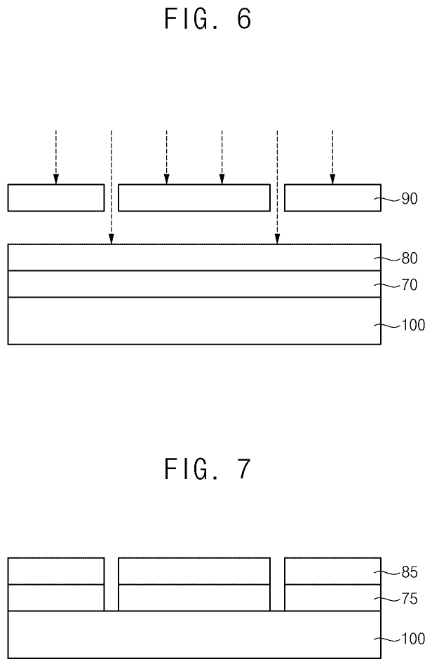

FIG. 5 is a flowchart illustrating a method of correcting a layout of a pattern, a method of manufacturing a photomask using the same, and a method of forming a pattern using the same in accordance with example embodiments of the present inventive concept. FIGS. 6 and 7 are cross-sectional views illustrating the method of forming the pattern.

The method of correcting the layout of the pattern may include the method of calculating the MEEF or the REEF illustrated with reference to FIGS. 1 to 4, and thus repeated explanations are omitted herein.

Referring to FIG. 5, in step S110, a layout of a pattern to be implemented on a wafer may be designed.

In example embodiments of the present inventive concept, the designing of the layout of the pattern may include designing a mask target of a photoresist that may be used in an exposure process for forming the pattern.

In step S120, a MEEF and a REEF may be calculated by performing steps S10 to S60 illustrated with reference to FIGS. 1 to 4.

In step S130, an OPC model and a PPC model may be generated by using the calculated MEEF and REEF.

In step S140, an OPC and a PPC may be performed by using the generated OPC model and the PPC model, so that the designed layout of the pattern, that is, a layout of the mask target may be firstly corrected.

In step S150, a first photomask may be manufactured based on the firstly corrected layout of the pattern, that is, the firstly corrected layout of the mask target.

In step S160, a first photomask may be manufactured based on the firstly corrected layout of the pattern, that is, the firstly corrected layout of the mask target.

In step S160, a first etching object layer and a first photoresist layer may be sequentially formed on a substrate. Then, an exposure process and a developing process may be performed on the first photoresist layer by using the first photomask to form a first photoresist pattern, and an etching process may be performed on the first etching object layer by using the first photoresist pattern as an etching mask to form a first pattern.

In step S170, the firstly corrected layout of the pattern, that is, the firstly corrected layout of the mask target and a layout of the first photoresist pattern may be compared with each other to determine if there is an error. For example, the layout of the first photoresist pattern may be checked for errors by comparing it to the firstly corrected layout of the mask target. Additionally, a layout of an ADI target for forming the first photoresist pattern and a layout of the first pattern may be compared with each other to determine if there is an error. For example, the layout of the first pattern may be checked for errors by comparing it to the layout of the ADI target for forming the first photoresist pattern.

In step S180, a MEEF and a REEF may be calculated, and the firstly corrected layout of the pattern, that is, the firstly corrected layout of the mask target may be secondly corrected based on the checked errors by using the calculated MEEF and REEF.

In step S190, a second photomask may be manufactured based on the secondly corrected layout of the pattern, that is, the secondly corrected mask target.

Referring to FIG. 5 together with FIGS. 6 and 7, in step S200, an exposure process and a developing process may be performed by using the second photomask to form a second photoresist pattern, and an etching process may be performed using the second photoresist pattern as an etching mask to form a second pattern.

That is, a second etching object layer 70 and a second photoresist layer 80 may be sequentially formed on a substrate 100, and an exposure process and a developing process may be performed on the second photoresist layer 80 by using the second photomask 90 so that the second photoresist layer 80 may be transformed into a second photoresist pattern 85 having a desired layout. An etching process may be performed on the second etching object layer 70, which is disposed on the substrate 100, by using the second photoresist pattern 85 as an etching mask to form a second pattern 75 having a desired layout. The second photoresist pattern 85 may be removed.

While the present inventive concept has been described with reference to example embodiments thereof, it will be understood by those of ordinary skill in the art that various changes in form and details may be made thereto without departing from the spirit and scope of the present inventive concept.

What is claimed is:

1. A method of correcting a layout of a pattern, the method comprising:
designing a layout of an original after development inspection (ADI) target, wherein the original ADI target includes target patterns;
applying a plurality of biases to the target patterns to design a random biased ADI target, wherein the random biased ADI target includes biased patterns;
manufacturing a single first photomask and a single second photomask corresponding to the original ADI target and the random biased ADI target, respectively;
performing an exposure process and a developing process on a photoresist layer by using the first and second photomasks to form first and second photoresist patterns, respectively, in the photoresist layer;
performing an etching process on an etching object layer by using the first and second photoresist patterns to form first and second patterns, respectively, in the etching object layer;
measuring critical dimensions (CDs) of the first and second patterns to calculate a retarget error enhancement factor (REEF);
generating a process proximity correction (PPC) model by using the REEF; and
performing a PPC by using the PPC model to correct the layout of the original ADI target.

2. The method of claim 1, wherein the biases include a horizontal bias, a vertical bias and a global bias.

3. The method of claim 2, wherein each of the horizontal bias, the vertical bias and the global bias includes a plus bias and a minus bias.

4. The method of claim 2, wherein each of the horizontal bias, the vertical bias and the global bias has a plurality of values within a predetermined range.

5. The method of claim 1, wherein the target patterns are classified into a plurality of groups, and
wherein different biases are applied to the target patterns of the plurality of groups, respectively.

6. The method of claim 1, wherein:
each of the target patterns included in the original ADI target has first and second lengths in first and second directions, respectively, wherein the second direction is substantially perpendicular to the first direction,
each of the biased patterns included in the random biased ADI target has third and fourth lengths in the first and second directions, respectively, and
the CDs of the first and second patterns include fifth and sixth lengths, respectively, in the first direction.

7. The method of claim 6, wherein the REEF is calculated based on a difference between the third length and the first length, a difference between the fourth length and the second length, and a difference between the sixth length and the fifth length.

8. The method of claim 7, wherein the REEF is calculated through dividing Δcd by a₀Δtarget+a₁Δref+a₂ΔtargetΔref+a₃Δtarget²+a₄Δref² based on following formula,
$$Δ cd = {a}_{0} Δ target + {a}_{1} Δ ref + {a}_{2} Δ target Δ ref + {a}_{3} Δ {target}^{2} + {a}_{4} Δ {ref}^{2} , \qquad < formula >$$
wherein Δtarget is the difference between the third length and the first length, Δref is the difference between the fourth length and the second length, Δcd is the difference between the sixth length and the fifth length, and each of a₀, a₁, a₂, a₃, and a₄ are constants.

9. The method of claim 8, wherein a₀, a₁, a₂, a₃, and a₄ are calculated by regression analysis based on differences between the third length and the first length, differences between the fourth length and the second length, and differences between the sixth length and the fifth length.

10. A method of correcting a layout of a pattern, the method comprising:
designing a layout of an original mask target, wherein the original mask target includes target patterns;
applying a plurality of biases to the target patterns to design a random biased mask target, wherein the random biased mask target includes biased patterns;
manufacturing a single first photomask and a single second photomask corresponding to the original mask target and the random biased mask target, respectively;
performing an exposure process and a developing process on a photoresist layer by using the first and second photomasks to form first and second photoresist patterns, respectively;
measuring critical dimensions (CDs) of the first and second photoresist patterns to calculate a mask error enhancement factor (MEEF);
generating an optical proximity correction (OPC) model by using the MEEF; and
performing an OPC by using the OPC model to correct the layout of the original mask target.

11. The method of claim 10, wherein the biases include a horizontal bias, a vertical bias and a global bias.

12. The method of claim 11, wherein each of the horizontal bias, the vertical bias and the global bias includes a plus bias and a minus bias.

13. The method of claim 11, wherein each of the horizontal bias, the vertical bias and the global bias has a plurality of values within a predetermined range.

14. The method of claim 10, wherein the target patterns are classified into a plurality of groups, and
wherein different biases are applied to the target patterns of the plurality of groups, respectively.

15. The method of claim 10, wherein:
each of the target patterns included in the original mask target has first and second lengths in first and second directions, respectively, wherein the second direction is substantially perpendicular to the first direction,
each of the biased patterns included in the random biased mask target has third and fourth lengths in the first and second directions, respectively, and
the CDs of the first and second photoresist patterns include fifth and sixth lengths, respectively, in the first direction.

16. The method of claim 15, wherein the MEEF is calculated based on a difference between the third length and the first length, a difference between the fourth length and the second length, and a difference between the sixth length and the fifth length.

17. The method of claim 16, wherein the MEEF is calculated through dividing Δcd by a₀Δtarget+a₁Δref+a₂ΔtargetΔref+a₃Δtarget²+a₄Δref² based on following formula,
$$Δ cd = {a}_{0} Δ target + {a}_{1} Δ ref + {a}_{2} Δ target Δ ref + {a}_{3} Δ {target}^{2} + {a}_{4} Δ {ref}^{2} , \qquad < formula >$$
wherein Δtarget is the difference between the third length and the first length, Δref is the difference between the fourth length and the second length, Δcd is the difference between the sixth length and the fifth length, and each of a₀, a₁, a₂, a₃, and a₄ are constants.

18. The method of claim 17, wherein a₀, a₁, a₂, a₃, and a₄ are calculated by regression analysis based on differences between the third length and the first length, differences between the fourth length and the second length, and differences between the sixth length and the fifth length.

19. A method of forming a pattern, the method comprising:
designing a layout of an original after development inspection (ADI) target, wherein the original ADI target includes target patterns;
applying a plurality of biases to the target patterns to design a random biased ADI target, wherein the random biased ADI target includes biased patterns;
manufacturing a single first photomask and a single second photomask corresponding to the original ADI target and the random biased ADI target, respectively;
performing an exposure process and a developing process on a photoresist layer by using the first and second photomasks to form first and second photoresist patterns, respectively, in the photoresist layer;
performing an etching process on a first etching object layer by using the first and second photoresist patterns to form first and second patterns, respectively, in the etching object layer;
measuring critical dimensions (CDs) of the first and second patterns to calculate a retarget error enhancement factor (REEF);
generating a process proximity correction (PPC) model by using the REEF;
performing a PPC by using the PPC model to firstly correct the layout of the original ADI target;
manufacturing a third photomask based on the firstly corrected layout of the original ADI target;
sequentially forming a second etching object layer and a second photoresist layer on a first substrate;
performing an exposure process and a developing process on the second photoresist layer by using the third photomask to form a third photoresist pattern in the second photoresist; and
performing an etching process on the second etching object layer by using the third photoresist pattern as an etching mask to form a third pattern in the second etching object layer.

20. The method of claim 19, further comprising:
checking an error between the firstly corrected layout of the original ADI target and a layout of the third pattern;
secondly correcting the firstly corrected layout of the original ADI target based on the checked error by using the REEF;
manufacturing a fourth photomask based on the secondly corrected layout of the original ADI target;
sequentially forming a third etching object layer and a third photoresist layer on a second substrate;
performing an exposure process and a developing process on the third photoresist layer by using the fourth photomask to form a fourth photoresist pattern in the third photoresist layer; and
performing an etching process on the third etching object layer by using the fourth photoresist pattern as an etching mask to form a fourth pattern in the third etching object layer.
